(19) United States
(12) Patent Application Publication
(10) Pub. No.: US 2025/0234488 A1
(43) Pub. Date: Jul. 17, 2025

(54) LIQUID COOLING SYSTEM HAVING NO DISCONNECTABLE FLUIDIC CONNECTIONS BETWEEN A FLUID INLET AND FLUID OUTLET

(71) Applicant: Lenovo Enterprise Solutions (Singapore) Pte. Ltd., Singapore (SG)

(72) Inventor: Tianyi Gao, Greensboro, NC (US)

(21) Appl. No.: 18/412,668

(22) Filed: Jan. 15, 2024

(51) Int. Cl. H05K 7/20; F28F 9/26; F28F 13/08

(52) U.S. Cl. CPC H05K 7/20327; F28F 9/26; F28F 13/08

(57) ABSTRACT

A system includes a fluid conduit for circulating a cooling fluid, the fluid conduit including a fluid inlet, fluid outlet, and plurality of conduit branches including first and second conduit branches. Each conduit branch is formed between the fluid inlet and outlet, and the fluid conduit is a unitary component with no disconnectable fluidic connections between the fluid inlet and outlet. A first cooling core has a first base for thermal communication with a first electronic component on a circuit board and a first lateral channel that is physically disconnectably connectable to the first conduit branch, and a second cooling core has a second base for thermal communication with a second electronic component installed on the circuit board and a second lateral channel that is physically disconnectably connectable to the second conduit branch. Physically connecting the channels and branches establishes thermal communication between the cooling core and the conduit branch.

### BACKGROUND

The present disclosure relates to devices that provide liquid cooling of electronics, such as certain components of a computer.

### Background of the Related Art

Computing devices are trending toward smaller devices and form factors, allowing more computing devices to occupy a given amount of space. As a result, a greater amount of power may be consumed by the devices that occupy a given chassis, rack or datacenter. This greater power density results in the generation of an additional heat load that must be efficiently removed so that the computing devices are allowed to operate at a suitable temperature. Sets of fans have been used to force air through each chassis and across the computing devices to cool the devices, but there are limits to the efficiency of air cooling. For example, the operation of the fans consumes additional power and the chassis must be designed with suitable air passageways to cool each device. To cool high performance computing devices with a high power density, liquid cooling modules are becoming more prevalent.

Despite the benefits of liquid cooling, the use of liquid cooling modules poses a risk of liquid leaks within an individual computing device and throughout a computing system. A high level of attention and care must be given to assuring that each liquid cooling module is installed properly and each connection between liquid-filled conduits is firmly and tightly connected. However, there are various reasons that a connection may develop a leak over time or that liquid will be released during a disconnection operation.

### BRIEF SUMMARY

Some embodiments provide a system or assembly comprising a fluid conduit for circulating a cooling fluid, wherein the fluid conduit includes a fluid inlet, a fluid outlet, and a plurality of conduit branches including a first conduit branch and a second conduit branch. Each of the plurality of conduit branches are formed between the fluid inlet and the fluid outlet, and the fluid conduit is a unitary component with no disconnectable fluidic connections between the fluid inlet and the fluid outlet. The system further comprises a plurality of cooling cores including a first cooling core and a second cooling core. The first cooling core has a first base for thermal communication with a first electronic component installed on a circuit board and a first lateral channel that is physically disconnectably connectable about an exterior surface of the first conduit branch, and the second cooling core having a second base for thermal communication with a second electronic component installed on the circuit board and a second lateral channel that is physically disconnectably connectable about an exterior surface of the second conduit branch, wherein physically connecting the first lateral channel to the first conduit branch establishes thermal communication between the first cooling core and the first conduit branch, and wherein physically connecting the second lateral channel to the second conduit branch establishes thermal communication between the second cooling core and the second conduit branch.

### BRIEF DESCRIPTION OF THE SEVERAL VIEWS OF THE DRAWINGS

FIG. 1 is a top view of a cooling module or system positioned in a server to be use for thermal management of the electronics within the server.

FIG. 2A is a top view of an alternative cooling module or system with cooling cores having different sizes, shapes and configurations positioned as needed for a given server.

FIG. 2B is a top view of a second alternative cooling module or system with a variety of cooling cores and a variety of conduit branches having different sizes and spacings as needed for a given server.

FIG. 3A is a side view of a cooling module or system including fluid conduit with cooling cores connected to the conduit branches, where the cooling system is being installed in a server chassis to provide thermal management of various electronics devices.

FIG. 3B is a side view of the cooling system of FIG. 3A after it has been installed in the server chassis.

FIGS. 4A-B are side views of cooling cores having a lateral channel connected to a conduit branch of the cooling system and a base in contact with an electronic device.

FIG. 5A is a perspective view of a single cooling core according to one embodiment.

FIG. 5B is a partial cut-away perspective view of the cooling core of FIG. 5A showing a set of internal fins in an upper region of a sealed internal chamber that would contain a phase change material.

FIG. 6 is a perspective view of a cooling core having two lateral channels with a rectangular profile for thermal communication with a conduit branch having a rectangular cross-section.

### DETAILED DESCRIPTION

Some embodiments provide a system or assembly comprising a fluid conduit for circulating a cooling fluid, wherein the fluid conduit includes a fluid inlet, a fluid outlet, and a plurality of conduit branches including a first conduit branch and a second conduit branch. Each of the plurality of conduit branches are formed between the fluid inlet and the fluid outlet, and the fluid conduit is a unitary component with no disconnectable fluidic connections between the fluid inlet and the fluid outlet. The system further comprises a plurality of cooling cores including a first cooling core and a second cooling core. The first cooling core has a first base for thermal communication with a first electronic component installed on a circuit board and a first lateral channel that is physically disconnectably connectable about an exterior surface of the first conduit branch, and the second cooling core having a second base for thermal communication with a second electronic component installed on the circuit board and a second lateral channel that is physically disconnectably connectable about an exterior surface of the second conduit branch, wherein physically connecting the first lateral channel to the first conduit branch establishes thermal communication between the first cooling core and the first conduit branch, and wherein physically connecting the second lateral channel to the second conduit branch establishes thermal communication between the second cooling core and the second conduit branch.

The system may be referred to as a fluid cooling system or fluid cooling module. A fluid cooling system according to some embodiments may be connected to an external source of cooling fluid (“a coolant”) to form a cooling loop. For example, the cooling fluid may be water, deionized water, inhibited glycol and water solutions, or a dielectric fluid. Accordingly, the fluid cooling system provide thermal management or cooling to electronic components on the circuit board by absorbing heat generated by the electronic components into the cooling core, transferring that heat from the cooling core to the fluid conduit, and withdrawing that heat in cooling fluid circulating through the fluid conduit. The external source of cooling fluid may include a pump so that the external source provides cool fluid supply at an elevated pressure to the fluid inlet of the fluid conduit and provides a warm fluid return from the fluid outlet of the fluid conduit such that the fluid circulates through the fluid conduit. Optionally, the external source may provide cooling fluid to a plurality of fluid cooling systems described herein. For example, the external source may provide a fluid supply manifold and a fluid return manifold in the back of a computer rack, where the manifolds have connectors for coupling with a plurality fluid cooling systems disposed in a plurality of rack-mounted computers or other information technology equipment that includes electronic components of a circuit board.

A “conduit” is pipe or tube having a channel through which a fluid may be conveyed. A conduit may have a circular cross-sectional profile, but this shape is not required. Rather, a conduit may have, without limitation, a rectangular cross-sectional profile. Furthermore, a conduit may have one cross-sectional profile along one section of the conduit and have another cross-sectional profile along another section of the conduit, yet the two sections may still suitably convey a fluid.

Embodiments of the fluid conduit preferably have a single fluid inlet and a single fluid outlet for connection to a cooling fluid supply line or manifold and a return line or manifold, respectively. A fluid supply line and a fluid return line may be a pair of dedicated fluid inlet/outlet tubes for connections to the fluid inlet and fluid outlet of the fluid conduit, whereas a fluid supply manifold and a fluid return manifold may provide fluid inlet/outlet connections for a plurality of fluid conduits. Optionally, the fluid inlet and fluid outlet may form blind mating connectors for connecting to blind mating connectors on the fluid supply/return line or manifold. Still further, the connectors may be dripless connectors.

Embodiments of the fluid conduit include a plurality of conduit branches including a first conduit branch and a second conduit branch. Optionally, the fluid conduit may include from 2 to 12 conduit branches. Each branch is fluidically connected for circulating cooling fluid there through as the cooling fluid moves from the fluid inlet to the fluid outlet. In some embodiments, the fluid conduit may form a first longitudinal conduit segment extending from the fluid inlet and a second longitudinal conduit segment extending from the fluid outlet. For example, the first and second longitudinal conduit segments may extend along opposing sides of the circuit board and may be parallel to each other. Accordingly, the plurality of conduit branches may be fluidically connected between the first and second longitudinal conduit segments and may be perpendicular to the first and second longitudinal conduit segments. Furthermore, each longitudinal conduit and each conduit branch may be substantially linear, but this is not required.

Embodiments of the fluid conduit form a unitary component with no disconnectable fluidic connections between the fluid inlet and the fluid outlet. These embodiments provide the technical advantage that there are no connectors within the region of the circuit board such that there is essentially no opportunity for leaks to occur. For example, each of the plurality of conduit branches may have a first open end welded to an opening in a side of the first longitudinal conduit segment and a second open end welded to an opening in a side of the second longitudinal conduit. While the fluid inlet and the fluid outlet may involve connectors that have the potential to leak, the fluid inlet and the fluid outlet are to be positioned outside a perimeter of the circuit board where they connect to an external cooling loop. There are no other disconnectable fluidic connections within the fluid conduit, such that the fluid conduit is positionable relative to the circuit board so that the plurality of conduit branches may extend over one or more areas of the circuit board without risk of a leaking connection.

In some embodiments, the circuit board is secured in a chassis and the fluid conduit is positioned or positionable within the chassis for cooling the electronics components on the circuit board. The fluid conduit may guide the circulation of cooling fluid through the chassis and the cooling cores may be in thermal communication with electronic components installed on the circuit board that is supported within the electronics chassis. For example, the electronics chassis may be a server chassis and the circuit board may support electronic components of the server, such as one or more processors, memory devices, data storage devices and/or power sources.

Each cooling core has a base for thermal communication with an electronic component installed on the circuit board and a lateral channel that is physically disconnectably connectable about an exterior surface of a conduit branch. Physically connecting the lateral channel to the conduit branch establishes thermal communication between the cooling core and the conduit branch. Accordingly, the system removes heat from the electronic components on the circuit board and the cooling fluid circulating through the fluid conduit removes heat from the system. More specifically, the base of a cooling core absorbs heat from an electronic component and transfers that heat throughout the cooling core. The conduit branch that is connected to the lateral channel of the cooling core absorbs heat from the cooling core in the region of the lateral channel.

In some embodiments, the lateral channels in a cooling core have an open side and two open ends for receiving the conduit branch. For example, with the cooling core base directed downward onto the top of an electronic component, the open side of the lateral channel may be directed upward away from the circuit board. With the lateral channel directed upward and the two ends being open, a conduit branch may be lowered or otherwise received into the lateral channel. The conduit branch is preferably positioned at or near the bottom of the lateral channel to increase a contact area between the conduit branch and the lateral channel. Optionally, a plurality of cooling cores may have lateral channels with the same dimensions and a plurality of conduit branches may have the same dimensions, such that any of the cooling cores may be connected to any of the conduit branches to provide sufficient cooling of the electronic components. Furthermore, because the cooling cores are components independent of the fluid conduit, the cooling cores may be connected at any point along a length of the conduit branch to align the cooling core with one or more of the electronic components. This flexibility in positioning of the cooling cores may be particularly easy where the conduit branch is linear and the lateral channel in the cooling core is also linear.

In some embodiments, the system may further comprise one or more thermal transfer pads (also referred to as thermally conductive pads). A thermal transfer pad is a pre-formed solid material that is used to fill air gaps that may be caused by imperfectly flat or smooth surface that should be in thermal contact. For example, there may be minor gaps or spaces between the exterior surface of a conduit branch and the walls of a lateral channel in the cooling core where it is desired to have good thermal communication. So, a thermal transfer pad may be positioned in the lateral channel and around the exterior surface of the conduit branch to improve thermal communication therebetween. Without limitation, a thermal transfer pad may be made with silicone or polysiloxane, silica gel or paraffin wax. While a thermal paste may be used in place of a thermal transfer pad, a thermal transfer pad is preferred since it will not spread beyond where it is positioned. In one embodiment, the system may comprise a first thermal transfer pad positionable within the first lateral channel to improve heat transfer between the first cooling core and the first conduit branch, and a second thermal transfer pad positionable within the second lateral channel to improve heat transfer between the second cooling core and the second conduit branch. Optionally, the thermal transfer pad may help to frictionally secure the connection of the cooling core to a conduit branch. Specifically, the thermal transfer pad may be slightly compressible or pliable such that the conduit branch may be pressed into the lateral channel with the thermal transfer pad wedged between the conduit branch and the walls of the lateral channel.

In some embodiments, any one or more of the cooling cores may be a block of material having a high thermal conductivity like copper, aluminum, other metal or ceramic. In alternative embodiments, any one or more of the cooling cores may be a phase change heat spreader, also known as a heat pipe. As the name suggests, a “phase change heat spreader” moves heat (thermal energy) from one place to another assisted by a change in phase of a material within the heat spreader. For example, the phase change heat spreader has a sealed internal chamber containing a phase change material, such as ammonia, methanol, ethanol or water, that changes between a liquid phase and a vapor phase to enhance conduction of thermal energy through the first phase change heat spreader. A preferred phase change heat spreader may have metal walls that surround and define the sealed internal chamber. Furthermore, the sealed internal chamber includes a lower region along the base of the cooling core and an upper region adjacent to the lateral channel. Heat absorbed by the first base (from an electronic component) causes the phase change material to evaporate from the lower region and subsequently condense in the upper region. The upper region of the cooling core will be cooler than the base due to thermal communication with the conduit branch through which a cooling fluid is circulating. In one option, the sealed internal chamber may include a plurality of metal fins that provide additional surface area for heat exchange and condensation to occur. For example, each metal fin may have a first end connected to the metal wall adjacent to the lateral channel of the cooling core and may extend into the upper region of the sealed internal chamber. Although it has been previously emphasized that there is no fluidic connection between any of the cooling cores and the fluid conduit including any of its conduit branches, it should be further pointed out that there is no fluid communication between the cooling fluid that circulates within the fluid conduit and the phase change material sealed within the plurality of cooling cores. This is a technical advantage because the pressure inside the phase change heat spreader will change with temperature and should not be coupled to the cooling fluid in the fluid conduit.

In some embodiments, a cooling core may have a plurality of lateral channels, including an additional lateral channel for physically disconnectably connecting about an exterior surface of an additional conduit branch. As with the first lateral channel, physically connecting the additional lateral channel to the additional conduit branch establishes thermal communication between the cooling core and the additional conduit branch. Accordingly, the number of lateral channels may be increased so that the cooling core has an equally increased number of conduit branches connected thereto for increase thermal cooling of one or more electronic components that are thermal communication with the base of the cooling core.

In some embodiments, the first conduit branch may have a rectangular cross-sectional profile, and the first lateral channel may have a rectangular cross-sectional profile that receives the first conduit branch for thermal communication there between. Thermal communication between a rectangular channel and a rectangular conduit branch may be established over a large surface area on opposing flat sides, and potentially also along the flat bottom. Accordingly, it is possible to have more contact area for heat transfer with a conduit branch having a rectangular cross-sectional area than with a conduit branch having a circular cross-sectional profile. Any or all of the conduit branches may also have a rectangular cross-sectional profile.

In some embodiments, the first cooling core may include a first mechanical fastener for securing the first conduit branch within the first lateral channel. The mechanical fastener could be a clasp or bar that extends over the open top of the lateral channel so that a conduit branch received within the lateral channel does not come out. Specifically, if the cooling system or module is fully assembled with cooling cores connected in a desired configuration, a mechanical fastener may secure the cooling core during installation of the cooling system into an operative position relative to a circuit board, such as within an electronics enclosure.

In some embodiments, the first conduit branch may have a first cross-sectional area for cooling fluid flow therethrough and the second conduit branch may have a second cross-sectional area for cooling fluid flow therethrough, wherein the first and second cross-sectional areas are different. A fluid conduit may have any number of conduit branches and those conduit branches may have any number of sizes and any spacing or placement desired. Specific embodiments of the system may have a configuration of conduit branches and cooling cores that reflect the thermal management requirements of the electronics layout on a particular circuit board, such as a server. The configuration may be modified for use with a different circuit board having a different electronic architecture, server layout, or power distribution characteristics.

In some embodiments, a system may include a set of cooling cores that vary in their widths, lengths, thicknesses, materials and/or construction (solid metal and/or internal chamber continuing a phase change fluid).

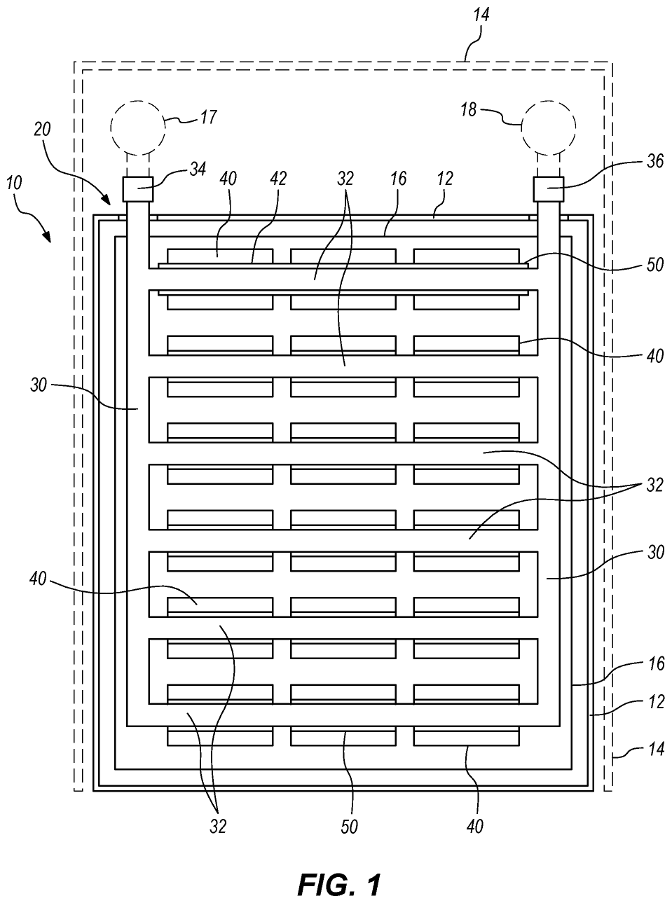

FIG. 1 is a top view of an installation 10 including a cooling module, assembly or system 20 positioned in a server chassis 12 that is further positioned in a bay or a rack 14. The system 20 is used for thermal management of electronics (not shown) installed on a circuit board 16 within the server chassis 12.

The system 20 includes a fluid conduit 30 that forms a plurality of conduit branches 32 (6 shown) extending over the circuit board 16. The fluid conduit 30 includes a fluid inlet 34 that receives a cooling fluid from a fluid supply manifold 17 and a fluid outlet 36 that delivers the cooling fluid to a fluid return manifold 18. Accordingly, a pressure differential between the fluid supply manifold 17 and the fluid return manifold 18 causes the cooling fluid to circulate through the fluid conduit 30 from the fluid inlet 34, through the plurality of conduit branches 32, to the fluid outlet 36. The only fluidic connectors of the fluid conduit 30 are located outside the perimeter of the circuit board 16 at the fluid inlet 34 and fluid outlet 36. The fluid inlet 34 and fluid outlet 36 may include fluidic connectors, such as blind mate connectors and/or no drip connectors.

The system 20 further includes a plurality of cooling cores 40 (18 shown). Each cooling core 40 is independently connected to one of the conduit branches 32. A lateral channel 42 in the cooling core 40 is sized to receiving a segment of a conduit branch 32. The connection between the cooling core 40 and the conduit branch 32 may be frictional with or without the use of a thermal transfer pad 50. Specifically, a thermal transfer pad 50 may be positioned between an exterior surface of the conduit branch 32 and a wall of the lateral channel 42.

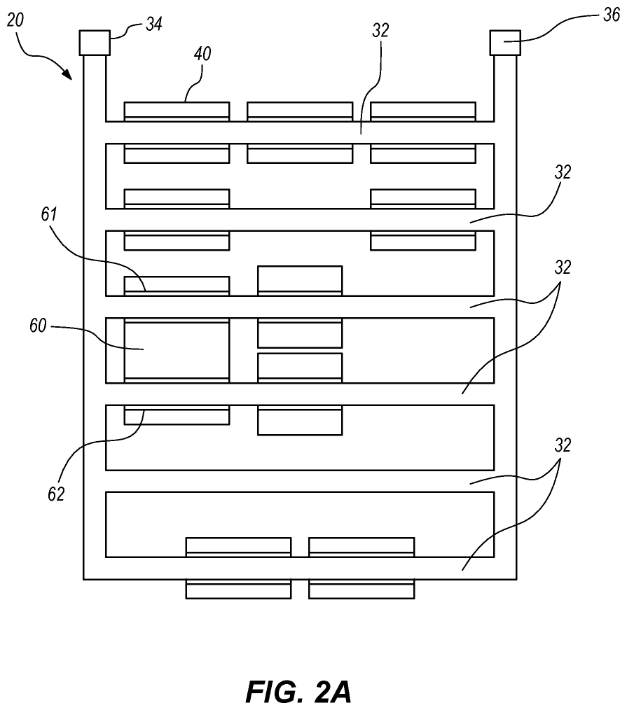

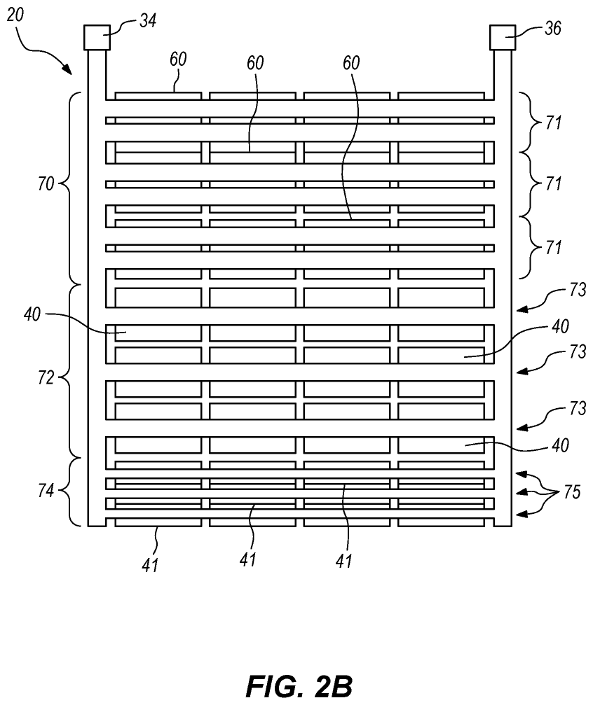

FIG. 2A is a top view of the cooling module, assembly or system 20 that has been reconfigured with a variety of cooling cores having different sizes, shapes and configurations positioned as needed for a given server. In addition to a few of the cooling cores 40, the system 20 includes a cooling core 60 that has two lateral channels 61, 62 for receiving two of the conduit branches 32. Also note that there are areas where there is no cooling core and other areas where there are fewer or repositioned cooling cores. Alternatively, the system could include more of the cooling cores 60 having two or more lateral channels connected to two or more conduit branches 32.

FIG. 2B is a top view of a second alternative configuration of the cooling module, assembly or system 20 with a variety of cooling cores and a variety of conduit branches having different sizes and spacings as needed for a given server. In this embodiment, the system 20 is divided into three regions, namely a high power electronics region 70 having rows of high power consuming electronics, a low power electronics region 72 having rows of low power consuming electronics, and a battery region 74 having rows of batteries. The high power electronics region 70 is shown having three rows 71 of four cooling cores 60, where each cooling core 60 is connected to two conduit branches. The low power electronics region 72 is shown having three rows 73 of cooling cores 40, where each cooling core 40 is connected to one conduit branch. The battery region 74 is shown having three rows 75 of cooling cores 41, where each cooling core 41 is connected to one conduit branch. However, the cooling cores 41 and associated conduit branches are much smaller.

When viewing FIGS. 1, 2A and 2B, it should be apparent that the system 20 provides a flexible solution that can be configured to cool various electronics layouts and power densities.

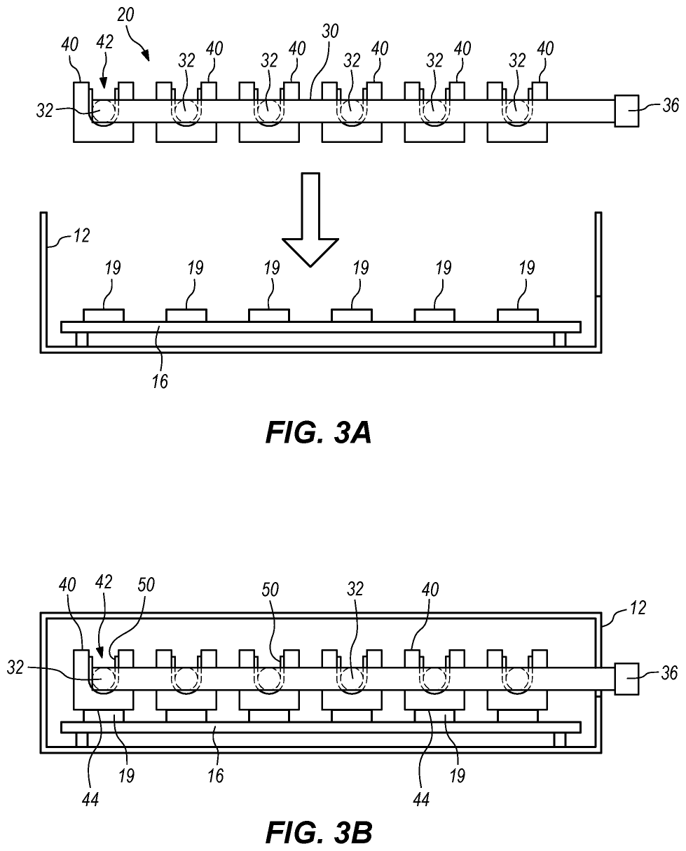

FIG. 3A is a side view of a cooling module or system 20 including the fluid conduit 30 with cooling cores 40 having their lateral channels 42 connected to the conduit branches 32. The cooling system 20 is ready to be installed in the server chassis 12 to provide thermal management of various electronics devices 19 installed on the circuit board 16.

FIG. 3B is a side view of the cooling system 20 of FIG. 3A after it has been installed in the server chassis 12. Specifically, the base 44 of each cooling core 40 is in thermal contact or communication with one of the electronic components 19.

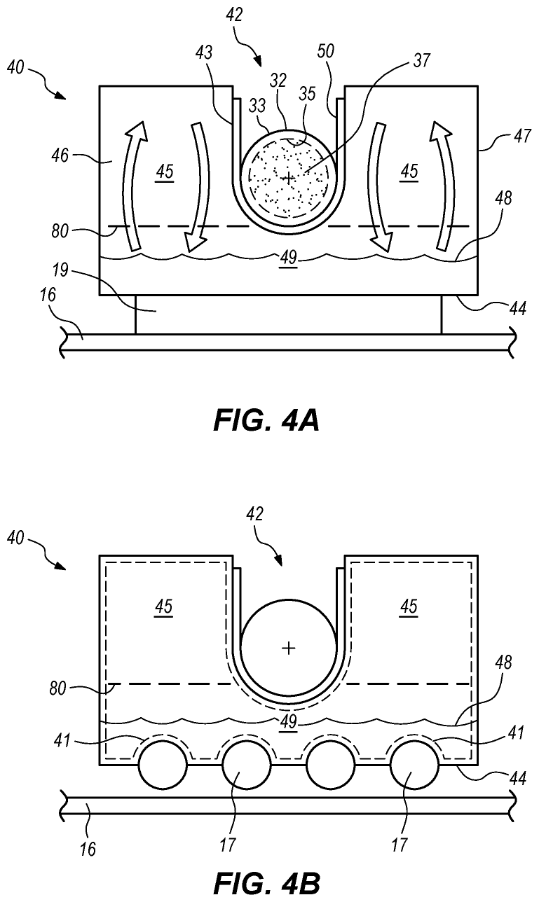

FIGS. 4A-B are side views of two different cooling cores 40 having a lateral channel 42 connected to a conduit branch 32 of the cooling system and a base 44 in contact (thermal communication) with an electronic device 19 or set of batteries 17. The lateral channel 42 is open to the top and to the ends (into and out of the page). As shown, the bottom of the lateral channel 42 is semi-circular to engage the outer surface of the conduit branch 32 having a circular cross-sectional profile. For example, the conduit branch 32 has an exterior surface 33 and an interior wall 35 and may be filled with a circulating cooling fluid 37. A thermal transfer pad 50 is positioned, and possibly wedged, between the exterior surface 33 of the conduit branch 32 and the side wall 43 of the lateral channel 42. Accordingly, there may be a frictional connection therebetween as well as a good thermal connection to support heat transfer from the cooling core 40 to the conduit branch 32.

Although the cooling core 40 may be made with a block of material having a high thermal conductivity like copper, aluminum, other metal or ceramic, the cooling core 40 is illustrated as a phase change heat spreader, also known as a heat pipe. The phase change heat spreader has a sealed internal chamber 46 containing a phase change material 48, such as ammonia, methanol, ethanol or water, that changes between a liquid phase and a vapor phase to enhance conduction of thermal energy through the first phase change heat spreader. A preferred phase change heat spreader may have metal walls 47 that surround and define the sealed internal chamber. Furthermore, the sealed internal chamber 46 includes a lower region 49 along the base 44 of the cooling core and an upper region 45 adjacent the lateral channel. Heat absorbed by the base 44 (from an electronic component 19) causes the phase change material 48 to evaporate from the lower region (see the bold upward arrows) and subsequently condense (see the bold downward arrows) in the upper region 45 and return to the lower region 49. The upper region 45 of the cooling core will be cooler than the base 44 due to thermal communication with the conduit branch 32 through which the cooling fluid 37 is circulating. In one option, the sealed internal chamber 46 may include a plurality of metal fins 80 (upward from the dashed line) that provide additional surface area for heat exchange and condensation to occur. For example, each metal fin 80 may have a first end connected to the metal wall 45 adjacent to the lateral channel 42 of the cooling core and may extend laterally into the upper region 45 of the sealed internal chamber. Although it has been previously emphasized that there is no fluidic connection between any of the cooling cores and the fluid conduit including any of its conduit branches, it should be further pointed out that there is no fluid communication between the cooling fluid 37 that circulates within the fluid conduit 32 and the phase change material 48 sealed within the cooling core 40.

In FIG. 4B, the cooling core 40 has similar construction except that the base 44 has a series of four arcs 41 configured for surface-to-surface thermal communication with four batteries or other type of energy cells 17.

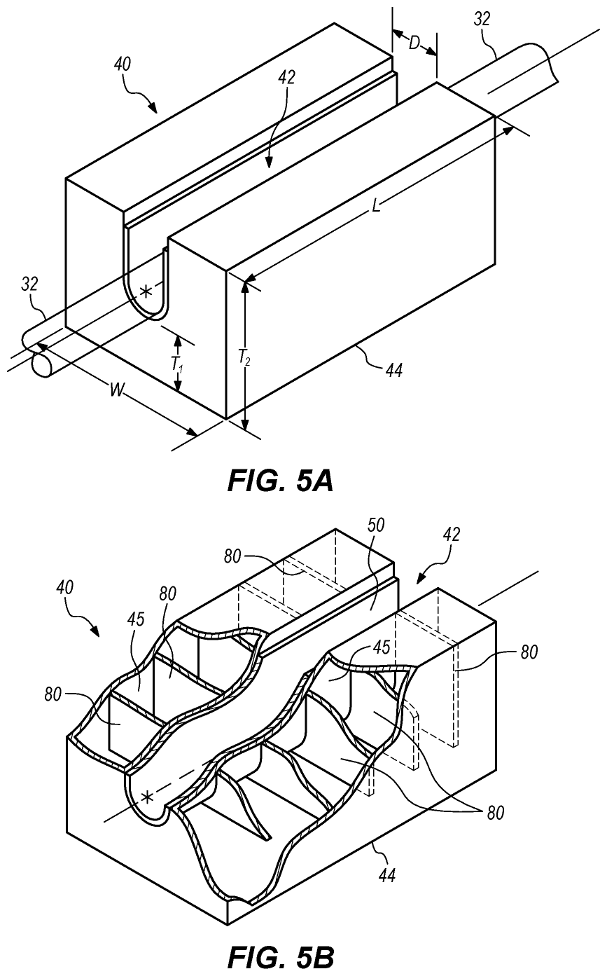

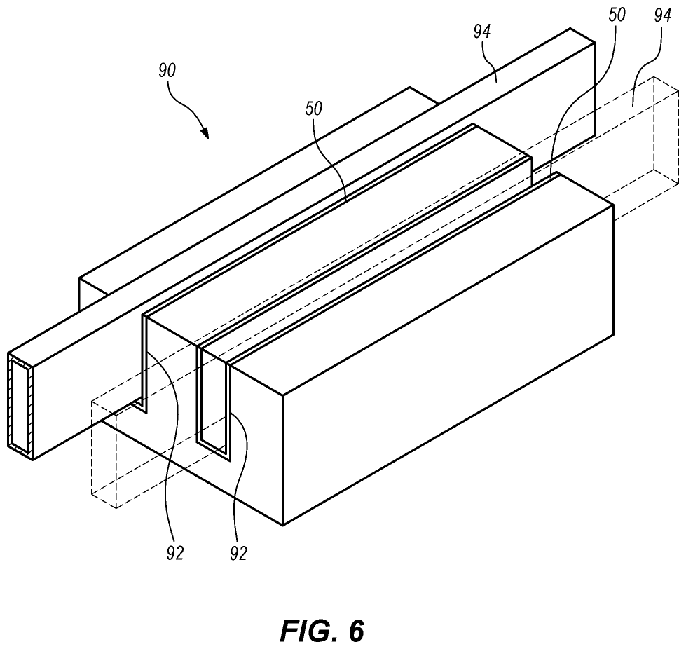

FIG. 5A is a perspective view of a single cooling core 40 according to one embodiment. In this illustration, the cooling core 40 has a width W, a length L, a thickness T₁ from the base 44 to the bottom of the lateral channel 42, a total thickness T₂, and a lateral channel width or distance D for receive a conduit branch 32. Any or all of these parameters may be modified to provide the necessary thermal management of an electronic component and meet any specific physical constraints.

FIG. 5B is a partial cut-away perspective view of the cooling core 40 of FIG. 5A showing a set of internal fins 80 in the upper region 45 of a sealed internal chamber that would contain a phase change material. Note that the internal fins 80 may extend to the top of the internal chamber, but preferably do not extend to the base 44 (see also FIGS. 4A and 4B).

FIG. 6 is a perspective view of a cooling core 90 having two lateral channels 92 that each have a rectangular profile for thermal communication with a pair of conduit branches 94 that each have a rectangular cross-section. The optional thermal transfer pad 50 is shown in use between each conduit branch 94 and the associated lateral channel 92. Other aspects of the cooling core 90 may be constructed as in any one or more of the other embodiments described herein.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. A system, comprising:
a fluid conduit for circulating a cooling fluid, wherein the fluid conduit includes a fluid inlet, a fluid outlet, and a plurality of conduit branches including a first conduit branch and a second conduit branch, wherein each of the plurality of conduit branches are formed between the fluid inlet and the fluid outlet, and wherein the fluid conduit is a unitary component with no disconnectable fluidic connections between the fluid inlet and the fluid outlet; and
a plurality of cooling cores including a first cooling core and a second cooling core, the first cooling core having a first base for thermal communication with a first electronic component installed on a circuit board and a first lateral channel that is physically disconnectably connectable about an exterior surface of the first conduit branch, and the second cooling core having a second base for thermal communication with a second electronic component installed on the circuit board and a second lateral channel that is physically disconnectably connectable about an exterior surface of the second conduit branch, wherein physically connecting the first lateral channel to the first conduit branch establishes thermal communication between the first cooling core and the first conduit branch, and wherein physically connecting the second lateral channel to the second conduit branch establishes thermal communication between the second cooling core and the second conduit branch.

2. The system of claim 1, wherein there is no fluid communication between the cooling fluid in the fluid conduit and the plurality of cooling cores.

3. The system of claim 1, wherein the first and second lateral channels have an open side and two open ends for receiving the first conduit branch.

4. The system of claim 1, wherein the first lateral channel in the first cooling core is also physically disconnectably connectable about the exterior surface of the second conduit branch, and wherein the second lateral channel in the second cooling core is also physically disconnectably connectable about the exterior surface of the first conduit branch.

5. The system of claim 1, wherein the first conduit branch is spaced apart from the second conduit branch, and wherein the first and second conduit branches are configured to extend over the circuit board and the first and second electronic components installed on the circuit board.

6. The system of claim 1, wherein the first cooling core is a first phase change heat spreader, wherein the first phase change heat spreader has a sealed internal chamber containing a phase change material that changes between liquid and vapor phases to enhance conduction of thermal energy through the first phase change heat spreader.

7. The system of claim 6, wherein the first phase change heat spreader has metal walls formed around the sealed internal chamber.

8. The system of claim 7, wherein the sealed internal chamber includes a lower region along the base of the first cooling core and an upper region adjacent the first lateral channel, wherein heat conduction from the first base causes the phase change material to evaporate from the lower region and condense in the upper region.

9. The system of claim 8, wherein the sealed internal chamber includes a plurality of metal fins, each metal fin having a first end connected to the metal wall adjacent the lateral channel of the first cooling core and extending into the upper region of the sealed internal chamber.

10. The system of claim 1, wherein the first conduit branch of the fluid conduit is linear and the first lateral channel in the first cooling core is linear.

11. The system of claim 10, wherein the first cooling core may be connected at any point along a length of the linear first conduit branch to align the first cooling core with the first electronic component.

12. The system of claim 1, wherein the plurality of cooling cores includes a third cooling core having a third base for thermal communication with a third electronic component installed on the circuit board and a third lateral channel that is physically disconnectably connectable about an exterior surface of the first conduit branch, wherein physically connecting the third lateral channel to the first conduit branch establishes thermal communication between the third cooling core and the first conduit branch.

13. The system of claim 1, further comprising:
a first thermal transfer pad positionable within the first lateral channel to improve heat transfer between the first cooling core and the first conduit branch; and
a second thermal transfer pad positionable within the second lateral channel to improve heat transfer between the second cooling core and the second conduit branch.

14. The system of claim 1, wherein the fluid conduit is positionable relative to the circuit board so that the plurality of conduit branches extend over one or more areas of the circuit board while the fluid inlet and the fluid outlet are positioned beyond a perimeter of the circuit board for connecting to an external cooling loop that is located outside the perimeter of the circuit board.

15. The system of claim 1, wherein the first cooling core includes an additional lateral channel for physically disconnectably connecting about an exterior surface of an additional conduit branch, wherein physically connecting the additional lateral channel to the additional conduit branch establishes thermal communication between the first cooling core and the additional conduit branch.

16. The system of claim 1, wherein the fluid conduit forms a first longitudinal conduit extending from the fluid inlet and a second longitudinal conduit extending from the fluid outlet, wherein the first longitudinal conduit is parallel to the second longitudinal conduit, and wherein the plurality of conduit branches extend between the first and second longitudinal conduits and are perpendicular to the first and second longitudinal conduits.

17. The system of claim 1, wherein the first conduit branch has a rectangular cross-sectional profile, and wherein the first lateral channel has a rectangular cross-sectional profile that receives the first conduit branch for thermal communication there between.

18. The system of claim 1, wherein the first cooling core includes a first mechanical fastener for securing the first conduit branch within the first lateral channel.

19. The system of claim 1, wherein the first conduit branch has a first cross-sectional area for cooling fluid flow therethrough and the second conduit branch has a second cross-sectional area for cooling fluid flow therethrough, wherein the first and second cross-sectional areas are different.

20. The system of claim 1, wherein the fluid inlet and the fluid outlet each secure a blind mating connector for coupling with the external cooling loop.
